(19) United States
(12) Patent Application Publication
(10) Pub. No.: US 2025/0393297 A1
(43) Pub. Date: Dec. 25, 2025

(54) INTEGRATED BOOTSTRAP CIRCUIT FOR POWER CONVERTERS

(71) Applicant: Renesas Electronics America Inc., Milpitas, CA (US)

(72) Inventors: Dev Alok GIRDHAR, Indialantic, FL (US); Matthew Alan GRANT, Cary, NC (US); Brannon Craig HARRIS, Austin, TX (US)

(73) Assignee: Renesas Electronics America Inc., Milpitas, CA (US)

(21) Appl. No.: 18/750,493

(22) Filed: Jun. 21, 2024

(51) Int. Cl. H01L 27/06; H01L 29/861; H01L 29/872; H01L 29/94

(52) U.S. Cl. CPC H10D 84/811; H10D 1/665; H10D 8/411; H10D 8/60; H10D 8/605

(57) ABSTRACT

Semiconductor devices and integrated circuits implementing power converters are described. An integrated circuit integrated circuit can include a power stage, a driver and a bootstrap circuit. The driver can be configured to drive the power stage. The bootstrap circuit can be configured to drive a high-side switch in the power stage in a start-up process. The bootstrap circuit can include a capacitor and a diode. The power stage, the driver and the bootstrap circuit can be integrated on the same silicon. The capacitor can be implemented by at least one trench capacitor.

### BACKGROUND

The present disclosure relates in general to semiconductor devices and packages, more particularly, to power converters with integrated bootstrap circuit.

Power converters or voltage converters, such as buck converters and boost converters, can be used for converting an input voltage to an output voltage having a different voltage level. A buck converter, or step-down converter, can convert the input voltage into a lower voltage. A boost converter, or step-up converter, can convert the input voltage into a higher voltage. A buck-boost converter can step up or step down the input voltage. A voltage converter can include multiple switches that can be turned on and off by a pulse width modulated (PWM) control signal. A duty cycle of the PWM control signal can define an output voltage of the voltage converter. When the voltage converter is connected to a load, the load can demand a specific amount of power by drawing a specific amount of current, and the voltage converter can perform the voltage conversion to generate the output voltage that can deliver the power demanded by the load. The current being drawn by the load can be sensed and fed back to a controller of the power converter, and the controller can report the sensed current to a host processor for the host processor to run various applications, such as optimizing performance of the load.

### SUMMARY

In one embodiment, an integrated circuit for implementing a power converter is generally described. The integrated circuit can include a power stage, a driver and a bootstrap circuit. The driver can be configured to drive the power stage. The bootstrap circuit can be configured to drive a high-side switch in the power stage in a start-up process. The bootstrap circuit can include a capacitor and a diode. The power stage, the driver and the bootstrap circuit can be integrated on the same silicon. The capacitor can be implemented by at least one of a planar capacitor and a trench capacitor. The diode can be implemented by at least one of a planar diode and a trench diode.

In one embodiment, a voltage regulator is generally described. The voltage regulator can include an integrated circuit and a controller configured to control the integrated circuit. The integrated circuit can include a power stage, a driver and a bootstrap circuit. The driver can be configured to drive the power stage. The bootstrap circuit can be configured to drive a high-side switch in the power stage in a start-up process. The bootstrap circuit can include a capacitor and a diode. The power stage, the driver and the bootstrap circuit can be integrated on the same silicon. The capacitor can be implemented by at least one of a planar capacitor and a trench capacitor. The diode can be implemented by at least one of a planar diode and a trench diode.

In one embodiment, an integrated circuit for implementing a power converter is generally described. The integrated circuit can include a power stage, a driver and a bootstrap circuit. The driver can be configured to drive the power stage. The bootstrap circuit can be configured to drive a high-side switch in the power stage in a start-up process. The bootstrap circuit can include a capacitor and a diode. The power stage, the driver and the bootstrap circuit can be integrated on the same silicon. The capacitor can be implemented by at least one trench capacitor.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a system that can a power converter including an integrated bootstrap circuit in one embodiment.

FIG. 2 is a diagram illustrating a cross section of an embodiment of an integrated bootstrap circuit.

FIG. 3 is a diagram illustrating a cross section of another embodiment of an integrated bootstrap circuit.

FIG. 4 is a diagram illustrating a cross section of another embodiment of an integrated bootstrap circuit.

FIG. 5 is a diagram illustrating a cross section of another embodiment of an integrated bootstrap circuit.

FIG. 6 is a diagram illustrating a cross section of another embodiment of an integrated bootstrap circuit.

FIG. 7 is a diagram illustrating a cross section of another embodiment of an integrated bootstrap circuit.

FIG. 8 is a diagram illustrating a cross section of another embodiment of an integrated bootstrap circuit.

FIG. 9 is a diagram illustrating a cross section of another embodiment of an integrated bootstrap circuit.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

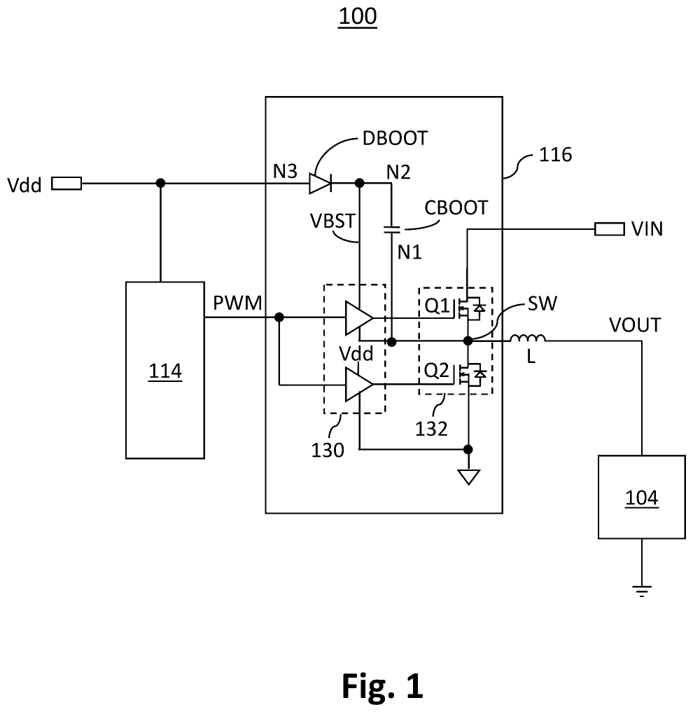

FIG. 1 illustrates an example of a system that can a power converter including an integrated bootstrap circuit in one embodiment. System 100 in FIG. 1 can be a power conversion system, according to a non-limiting example. As used herein, the terms block, module, circuit, system and the like may refer to various hardware, firmware, and software elements, or a combination thereof.

System 100 can include at least a controller 114 and an integrated circuit (IC) 116. IC 116 can include a driver circuit (or driver) 130, a power stage 132 and various other components. In one or more embodiments, IC 116 can further include storage devices such as memory devices and registers. Controller 114 can include one or more semiconductor devices implementing, for example, a microcontroller including hardware such as various analog and digital circuit components. Controller 114 can include, for example, a processor, central processing unit (CPU), field-programmable gate array (FPGA) or any other circuitry that is configured to control and operate various aspects of power stage 132. Controller 114 be configured to control various aspects of system 100. In one or more embodiments, a host computer can provide input to controller 114 for operating various aspects of system 100.

Controller 114 can be configured to execute instructions that may include firmware, software, and configuration data that may be embedded in or accessible by local memory in controller 114 or at least partially downloaded from a host computer. Controller 114 can be further configured to generate control signals, such as PWM signals (e.g., PWM in FIG. 1) and provide the PWM signals to driver circuit 130. Driver circuit 130 can receive the PWM signals and convert the PWM signals into drive signals that can be gate voltages for driving switches in power stage 132. Controller 114 can be further configured to monitor various parameters relating to operations in system 100 and based on the monitored parameters, determine whether to adjust the PWM signals for adjusting the on and off times of the switches in power stage 132.

Power stage 132 can include at least a pair of switches Q1, Q2. Switches Q1, Q2 can be, for example, metal oxide field effect transistors (MOSFETS). In one or more embodiments, switch Q1 and Q2 can be an N-type MOSFET. Switch Q1 can be arranged serially between an input voltage VIN and a switch node SW. In one embodiment, input voltage VIN can be a direct current (DC) voltage provided by a battery or a power supply. Switch Q2 can be arranged serially between switch node SW and ground. Driver circuit 130 can use PWM signals provided by controller 114 to generate drive signals and use the drive signals to drive switches Q1, Q2 alternately. As a result of driving switches Q1, Q2 alternately, an output voltage VOUT can be outputted from switch node SW. An inductor L can be connected between switch node SW and a load 104. The output voltage VOUT can supply power to load 104. Load 104 can be, for example, a central processing unit (CPU), a multiprocessor unit (MPU), a computer, or other electronic components that requires power to operate.

IC 116 can further include a diode DBOOT and a capacitor CBOOT. Capacitor CBOOT can be a bootstrap capacitor connected between a power supply Vdd and driver 130. In embodiments where switch Q1 is a N-type MOSFET, the diode DBOOT and capacitor CBOOT can function as a step-up circuit. When switch Q1 is turned off and switch Q2 is turned on, node SW will be close to or below ground and the capacitor CBOOT can be charged by the power supply Vdd, which is higher than ground. When switch Q1 is turned on and switch Q2 is turned off, SW node will climb up to voltage VIN, which can be greater than voltage Vdd. This results in stoppage of current flow through diode DBOOT as it become reverse biased. The capacitor CBOOT can then be discharged to provide an output of a bootstrap voltage VBST to the driver driving switch Q1. In an aspect, controller 114 can operate system 100 in a normal operation mode, in a low power mode, or shut off system 100. When the low power mode of system 100 is enabled, various connection paths among components in system 100 can be shut down or disconnected, and/or various functions can be disabled, to minimize current flow within system 100, thus preserving energy and power. For example, if a particular component is not needed, the particular component can be shut down to preserve power during the low power mode. To transition from the low power mode or from shut down back to normal operation mode, system 100 can go through a start-up process. The start-up process of system 100 can include biasing various components, turning on switch Q1, reconnecting paths that were disconnected, or other actions required for system 100 to operate under normal operation mode. The bootstrap voltage VBST being provided capacitor CBOOT may need to be at a level sufficient for turning on switch Q1 to allow system 100 to resume operation in the normal operation mode. In FIG. 1, a plurality of nodes N1, N2, N3 are shown. Node N1 is a node between CBOOT and switch node SW, node N2 is a node between CBOOT and the cathode of diode DBOOT, and node N3 is a node between the anode of diode DBOOT and power supply Vdd.

In an aspect, conventional power conversion systems include the drivers and the power stages in one IC package, and a bootstrap circuit outside and separated from the IC package. The discrete diode and discrete capacitor can be connected to the IC package using traces on printed circuit board (PCB). The bootstrap circuit can include the diode DBOOT and capacitor CBOOT as discrete devices that may occupy relatively large amount of board area on the PCB. To be described in more detail herein, the diode DBOOT and capacitor CBOOT can be integrated as part of IC 116 such that DBOOT, CBOOT, driver 130 and power stage 132 can be integrated or mounted as a monolithic IC or on a single piece of silicon. In order to integrate DBOOT and CBOOT in the same IC package as driver 130 and power stage 132, DBOOT and CBOOT can be implemented by different types of diodes and capacitors such that DBOOT and CBOOT can be integrated in the IC package. In one or more embodiments, different combinations of planar PN diodes, planar Schottky diodes, junction barrier Schottky diodes, trench MOS barrier Schottky diodes, trench MOS barrier PN diodes, planar capacitors and trench capacitors can be used for implementing DBOOT and CBOOT.

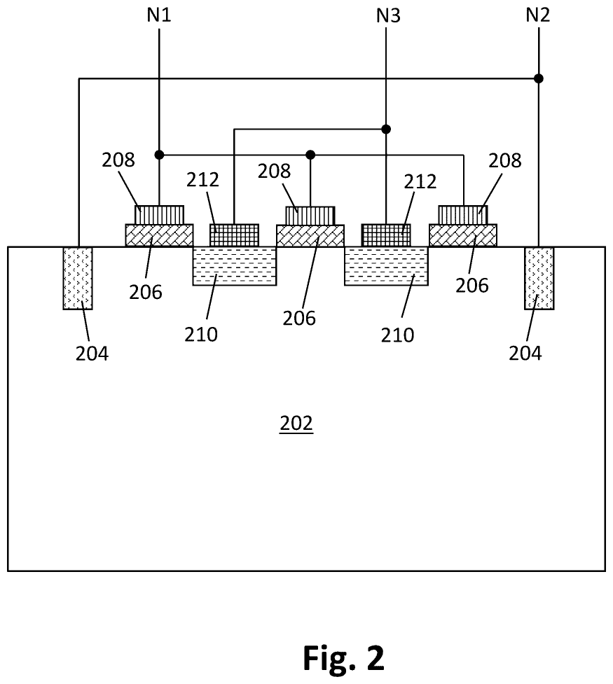

FIG. 2 is a diagram illustrating a cross section of an embodiment of an integrated bootstrap circuit. Description of FIG. 2 can reference components shown in FIG. 1. In the embodiment shown in FIG. 2, one or more PN diodes can implement boot diodes (e.g., DBOOT) and one or more planar MOS capacitor can implement boot capacitors (e.g., CBOOT). A cross section view of a portion of IC 116, that includes DBOOT and CBOOT, is shown in FIG. 2. In the example shown in FIG. 2, an N-well 202 that can be a part of IC 116 is shown. N-well 202 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 202 can be formed by implantation of dopant atoms such as phosphorus or arsenic. In some embodiments, N-well 202 can also be an N-epitaxial layer. N-well 202 can isolate bootstrap circuit components such as CBOOT and DBOOT from the rest of IC 116.

The bootstrap capacitor CBOOT shown in FIG. 1 can be implemented by one or more planar capacitors formed by a dielectric 206, an electrode 208 and the N-well 202. In one or more embodiments, N-well 202 can function as one of the conductive plates of the planar capacitors. Dielectric 206 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 208 can be formed by, for example, highly conductive materials such as doped polysilicon or metal (e.g., aluminum, copper, etc.). In one embodiment, dielectric 206 can have a thickness that is dependent on the voltage Vdd. Referring to FIG. 1, node N1 can be in contact with electrode 208.

The diode DBOOT can be implemented by one or more P+ diffusion regions 210 and N-well 202. The P+ diffusion regions 210 can be created by P-type diffusion in vacant areas of N-well 202. The P+ diffusion regions 210 can be formed by dopant materials such as Boron, Aluminum or Gallium. By forming P+ diffusion regions 210 in N-well 202, PN junctions can be formed between P+ diffusion regions 210 and N-well 202 to implement diode DBOOT. The P+ diffusion regions 210 can be the anode of diode DBOOT and N-well 202 can be the cathode of diode DBOOT. Contacts 212 (e.g., Ohmic contacts) can be placed on top of P+ diffusion regions 210 to connect diode DBOOT to other components. Referring to FIG. 1, node N3 can be in contact with contacts 212 such that the anode of diode DBOOT can be connected to Vdd.

One or more N+ diffusion regions 204 can be formed in N-well 202. The N+ diffusion regions 204 can be created by N-type diffusion in vacant areas of N-well 202. The N+ diffusion regions 204 can be formed by dopant materials such as Nitrogen, Phosphorus or Arsenic. N+ diffusion regions 204 can be used as contacts with other components. Referring to FIG. 1, node N2 can be in contact with N+ diffusion regions 204 to connect the cathode of diode DBOOT (e.g., N-well 202) to capacitor CBOOT.

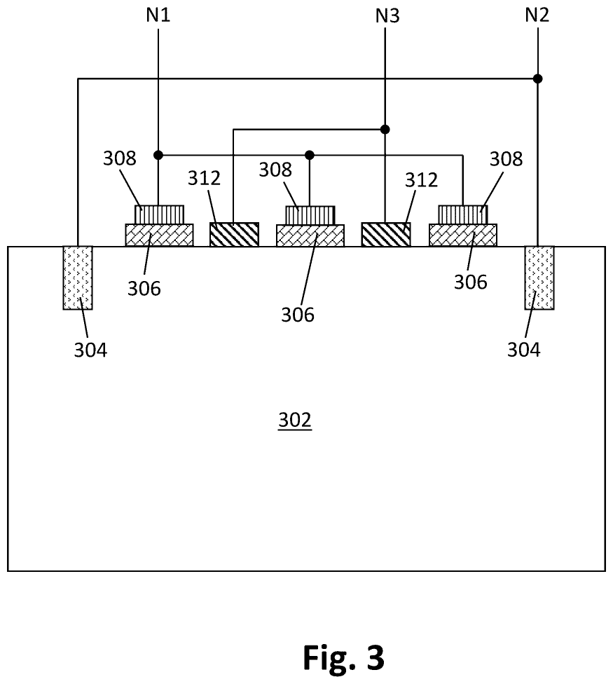

FIG. 3 is a diagram illustrating a cross section of another embodiment of an integrated bootstrap circuit. Description of FIG. 3 can reference components shown in FIG. 1 and FIG. 2. In the embodiment shown in FIG. 3, one or more planar Schottky diodes can implement boot diodes (e.g., DBOOT) and one or more planar MOS capacitors can implement a boot capacitors (e.g., CBOOT). A cross section view of a portion of IC 116, that includes DBOOT and CBOOT, is shown in FIG. 3. In the example shown in FIG. 3, an N-well 302 that can be a part of IC 116 is shown. N-well 302 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 302 can be formed by implantation of dopant atoms such as Phosphorus or Arsenic. In some embodiments, N-well 302 can also be an N-epitaxial layer. N-well 302 can isolate bootstrap circuit components such as CBOOT and DBOOT from the rest of IC 116.

The bootstrap capacitor CBOOT shown in FIG. 1 can be implemented by one or more planar capacitors formed by a dielectric 306, an electrode 308 and the N-well 302. In one or more embodiments, N-well 302 can function as one of the conductive plates of the planar capacitors. Dielectric 306 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 308 can be formed by, for example, highly conductive materials such as doped polysilicon or metal (e.g., aluminum, copper, etc.). In one embodiment, dielectric 306 can have a thickness that is dependent on the voltage Vdd. Referring to FIG. 1, node N1 can be in contact with electrode 308.

The diode DBOOT can be implemented by one or more planar Schottky diodes. To create planar Schottky diodes, one or more metal contacts 312 can be formed on N-well 302. Metal contacts 312 can be Schottky contacts, which can be metal-semiconductor contacts that create Schottky barriers with an N-type semiconductor such as N-well 302. In one or more embodiments, metal contacts 312 can be Titanium, Cobalt or Platinum contacts. In an aspect, when a metal is in contact with an N-type semiconductor and the work function (e.g., the minimum energy required to extract one electron) of the metal is greater than the work function of the N-type semiconductor, then a Schottky barrier is formed. Hence, the material forming metal contacts 312 has a work function greater than the work function of the materials forming N-well 302. Metal contacts 312 can function as the anode of diode DBOOT and N-well 302 can function as the cathode of diode DBOOT. Referring to FIG. 1, node N3 can be in contact with metal contacts 312 such that the anode of diode DBOOT can be connected to Vdd.

One or more N+ diffusion regions 304 can be formed in N-well 302. The N+ diffusion regions 304 can be created by N-type diffusion in vacant areas of N-well 302. The N+ diffusion regions 304 can be formed by dopant materials such as Nitrogen, Phosphorus or Arsenic. N+ diffusion regions 304 can be used as contacts with other components. Referring to FIG. 1, node N2 can be in contact with N+ diffusion regions 304 to connect the cathode of diode DBOOT (e.g., N-well 302) to capacitor CBOOT. In an aspect, the Schottky diode may be switched on at lower voltage and switch faster when compared to the PN junction diode in the embodiment shown in FIG. 2.

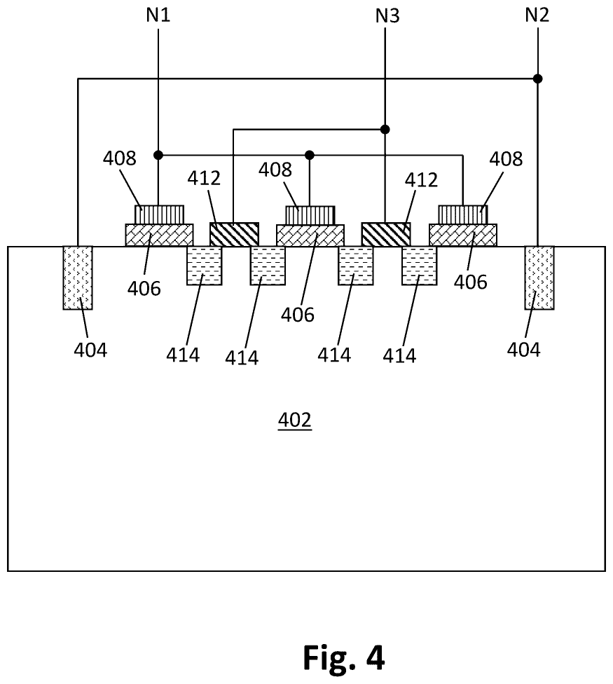

FIG. 4 is a diagram illustrating a cross section of another embodiment of an integrated bootstrap circuit. Description of FIG. 4 can reference components shown in FIG. 1 to FIG. 3. In the embodiment shown in FIG. 4, one or more planar Junction-barrier Schottky diodes can implement boot diodes (e.g., DBOOT) and one or more planar MOS capacitors can implement boot capacitors (e.g., CBOOT). A cross section view of a portion of IC 116, that includes DBOOT and CBOOT, is shown in FIG. 4. In the example shown in FIG. 4, an N-well 402 that can be a part of IC 116 is shown. N-well 402 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 402 can be formed by implantation of dopant atoms such as Phosphorus or Arsenic. In some embodiments, N-well 402 can also be an N-epitaxial layer. N-well 402 can isolate bootstrap circuit components such as CBOOT and DBOOT from the rest of IC 116.

The bootstrap capacitor CBOOT shown in FIG. 1 can be implemented by one or more planar capacitors formed by a dielectric 406, an electrode 408 and the N-well 402. In one or more embodiments, N-well 402 can function as one of the conductive plates of the planar capacitors. Dielectric 406 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 408 can be formed by, for example, highly conductive materials such as doped polysilicon or metal (e.g., aluminum, copper, etc.). In one embodiment, dielectric 406 can have a thickness that is dependent on the voltage Vdd. By way of example, the thickness of dielectric 406 increase as Vdd increases such that capacitor CBOOT can be thick enough to block voltages greater than Vdd. Referring to FIG. 1, node N1 can be in contact with electrode 408.

The diode DBOOT can be implemented by one or more planar Junction Barrier Schottky (JBS) diodes. P+ diffusion regions 414 can be formed in portions of N-well 402 that are exposed on the surface, such as portions not being covered by dielectric 406. The P+ diffusion regions 414 can be formed by dopant materials such as Aluminum, Boron or Gallium. After forming the P-type diffusion regions 414, one or more metal contacts 412 can be formed straddling on N-well 402 and on the P-type diffusion regions 414. Metal contacts 412 can be Ohmic on top of P-type diffusion region 414 and form a PN junction diode and Schottky diode on top of N-well 402. The metal contacts 412 contacting N-well 402 and P diffusion region 414 can form the JBS diodes. Metal contacts 412 can be Schottky contacts, which can be metal-semiconductor contacts that create Schottky barriers with an N-type semiconductor such as N-well 402. In one or more embodiments, metal contacts 412 can be Titanium, Cobalt or Platinum contacts. P+ diffusion regions 414 can be formed to protect the relatively fragile edges of the metal contacts 412 from breakdown. In an aspect, when a metal is in contact with an N-type semiconductor and the work function (e.g., the minimum energy required to extract one electron) of the metal is greater than the work function of the N-type semiconductor, then a Schottky barrier is formed. Hence, the material forming metal contacts 412 has a work function greater than the work function of the materials forming N-well 402. By forming P+ diffusion regions 414 in N-well 402, PN junctions can surround Schottky diodes formed by metal contacts 412 and N-well 402. The spacing between the P+ diffusion regions 414 can be defined for optimized blocking and conduction. Metal contacts 412 can function as the anode of diode DBOOT and N-well 402 can function as the cathode of diode DBOOT. Referring to FIG. 1, node N3 can be in contact with metal contacts 412 such that the anode of diode DBOOT can be connected to Vdd.

One or more N+ diffusion regions 404 can be formed in N-well 402. The N+ diffusion regions 404 can be created by N-type diffusion in vacant areas of N-well 402. The N+ diffusion regions 404 can be formed by dopant materials such as Nitrogen, Phosphorus or Arsenic. N+ diffusion regions 404 can be used as contacts with other components. Referring to FIG. 1, node N2 can be in contact with N+ diffusion regions 404 to connect the cathode of diode DBOOT (e.g., N-well 402) to capacitor CBOOT.

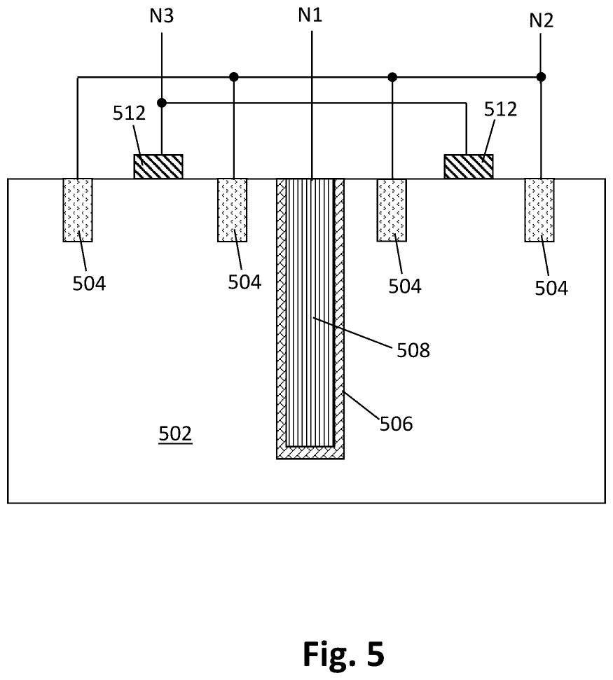

FIG. 5 is a diagram illustrating a cross section of another embodiment of an integrated bootstrap circuit. Description of FIG. 5 can reference components shown in FIG. 1 and FIG. 4. In the embodiment shown in FIG. 5, one or more planar Schottky diodes can implement boot diodes (e.g., DBOOT) and one or more trench MOS capacitors can implement boot capacitors (e.g., CBOOT). A cross section view of a portion of IC 116, that includes DBOOT and CBOOT, is shown in FIG. 5. In the example shown in FIG. 5, an N-well 502 that can be a part of IC 116 is shown. N-well 502 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 502 can be formed by implantation of dopant atoms such as Phosphorus or Arsenic. In some embodiments, N-well 502 can also be an N-epitaxial layer. N-well 502 can isolate bootstrap circuit components such as CBOOT and DBOOT from the rest of IC 116.

The bootstrap capacitor CBOOT shown in FIG. 1 can be implemented by one or more trench capacitors. The one or more trench capacitors can be formed inside N-well 502. A dielectric 506, an electrode 508 and the N-well 502 can implement a trench capacitor. In the embodiment shown in FIG. 5, one trench capacitor is shown but any arbitrary number of trench capacitors can be formed providing there is sufficient space in N-well 502. In one or more embodiments, N-well 502 can function as one of the conductive plates of the trench capacitors. Dielectric 506 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 508 can be formed by, for example, highly conductive materials such as doped polysilicon or metal (e.g., aluminum, copper, etc.). In one embodiment, dielectric 506 can have a thickness that is dependent on the voltage Vdd. By way of example, the thickness of dielectric 506 increase as Vdd increases such that capacitor CBOOT can be thick enough to block voltages greater than Vdd. In one embodiment, the depth of the trench capacitors in vertical direction can be less than the vertical depth of the N-well region 502. Referring to FIG. 1, node N1 can be in contact with electrode 508. In comparison to embodiments that uses planar capacitors, trench capacitors can reduce the amount of surface areas being occupied by capacitor components on the surface of IC 116, and the three-dimensional (3D) nature of trench capacitors can provide more capacitance per unit area on the surface of IC 116.

The diode DBOOT can be implemented by one or more planar Schottky diodes. To create planar Schottky diodes, one or more metal contacts 512 can be formed on N-well 502. Metal contacts 512 can be Schottky contacts, which can be metal-semiconductor contacts that create Schottky barriers with an N-type semiconductor such as N-well 502. In one or more embodiments, metal contacts 512 can be Titanium, Cobalt or Platinum contacts. In an aspect, when a metal is in contact with an N-type semiconductor and the work function (e.g., the minimum energy required to extract one electron) of the metal is greater than the work function of the N-type semiconductor, then a Schottky barrier is formed. Hence, the material forming metal contacts 512 has a work function greater than the work function of the materials forming N-well 502. Metal contacts 512 can function as the anode of diode DBOOT and N-well 502 can function as the cathode of diode DBOOT. Referring to FIG. 1, node N3 can be in contact with metal contacts 512 such that the anode of diode DBOOT can be connected to Vdd.

One or more N+ diffusion regions 504 can be formed in N-well 502. The N+ diffusion regions 504 can be created by N-type diffusion in vacant areas of N-well 502. The N+ diffusion regions 504 can be formed by dopant materials such as Nitrogen, Phosphorus or Arsenic. N+ diffusion regions 504 can be used as contacts with other components. Referring to FIG. 1, node N2 can be in contact with N+ diffusion regions 504 to connect the cathode of diode DBOOT (e.g., N-well 502) to capacitor CBOOT.

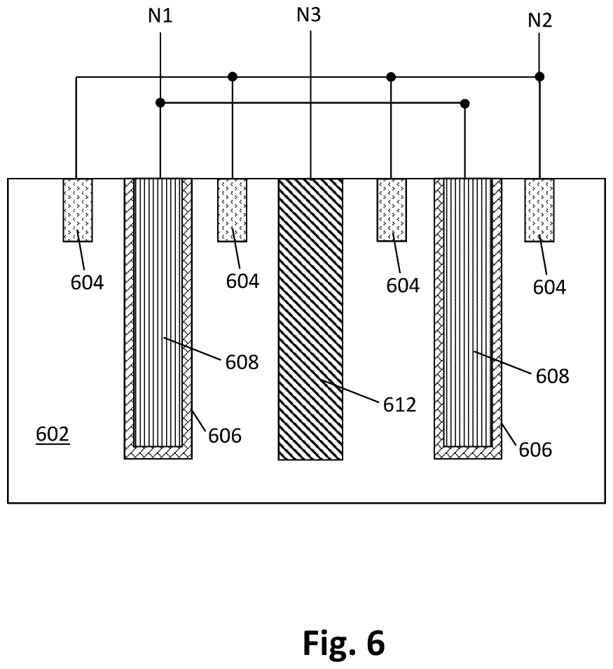

FIG. 6 is a diagram illustrating a cross section of another embodiment of an integrated bootstrap circuit. Description of FIG. 6 can reference components shown in FIG. 1 and FIG. 5. In the embodiment shown in FIG. 6, one or more trench Schottky diodes can implement boot diodes (e.g., DBOOT) and one or more trench MOS capacitors can implement boot capacitors (e.g., CBOOT). A cross section view of a portion of IC 116, that includes DBOOT and CBOOT, is shown in FIG. 6. In the example shown in FIG. 6, an N-well 602 that can be a part of IC 116 is shown. N-well 602 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 602 can be formed by implantation of dopant atoms such as Phosphorus or Arsenic. In some embodiments, N-well 602 can also be an N-epitaxial layer. N-well 602 can isolate bootstrap circuit components such as CBOOT and DBOOT from the rest of IC 116.

The bootstrap capacitor CBOOT shown in FIG. 1 can be implemented by one or more trench capacitors. The one or more trench capacitors can be formed inside N-well 602. A dielectric 606, an electrode 608 and the N-well 602 can implement a trench capacitor. In the embodiment shown in FIG. 6, two trench capacitors are shown but any arbitrary number of trench capacitors can be formed providing there is sufficient space in N-well 602. In one or more embodiments, N-well 602 can function as one of the conductive plates of the trench capacitors. Dielectric 606 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 608 can be formed by, for example, highly conductive materials such as doped polysilicon or metal (e.g., aluminum, copper, etc.). In one embodiment, dielectric 606 can have a thickness that is dependent on the voltage Vdd. By way of example, the thickness of dielectric 606 increase as Vdd increases such that capacitor CBOOT can be thick enough to block voltages greater than Vdd. Referring to FIG. 1, node N1 can be in contact with electrode 608. In comparison to embodiments that uses planar capacitors, trench capacitors can reduce the amount of surface areas being occupied by capacitor components on the surface of IC 116, and the three-dimensional (3D) nature of trench capacitors can provide more capacitance per unit area on the surface of IC 116.

The diode DBOOT can be implemented by one or more trench Schottky diodes. To create trench Schottky diodes, one or more metal contacts 612 can be formed in vacant areas or openings of on N-well 602. Metal contacts 612 can be Schottky contacts, which can be metal-semiconductor contacts that create Schottky barriers with an N-type semiconductor such as N-well 602. In one or more embodiments, metal contacts 612 can be Titanium, Cobalt or Platinum contacts. In an aspect, when a metal is in contact with an N-type semiconductor and the work function (e.g., the minimum energy required to extract one electron) of the metal is greater than the work function of the N-type semiconductor, then a Schottky barrier is formed. Hence, the material forming metal contacts 612 has a work function greater than the work function of the materials forming N-well 602. Metal contacts 612 can function as the anode of diode DBOOT and N-well 602 can function as the cathode of diode DBOOT. Referring to FIG. 1, node N3 can be in contact with metal contacts 612 such that the anode of diode DBOOT can be connected to Vdd. The depth of Schottky trench or metal contacts 612 can be similar or different from depth of trench capacitor or electrode 608.

One or more N+ diffusion regions 604 can be formed in N-well 602. The N+ diffusion regions 604 can be created by N-type diffusion in vacant areas of N-well 602. The N+ diffusion regions 604 can be formed by dopant materials such as Nitrogen, Phosphorus or Arsenic. N+ diffusion regions 604 can be used as contacts with other components. Referring to FIG. 1, node N2 can be in contact with N+ diffusion regions 604 to connect the cathode of diode DBOOT (e.g., N-well 602) to capacitor CBOOT.

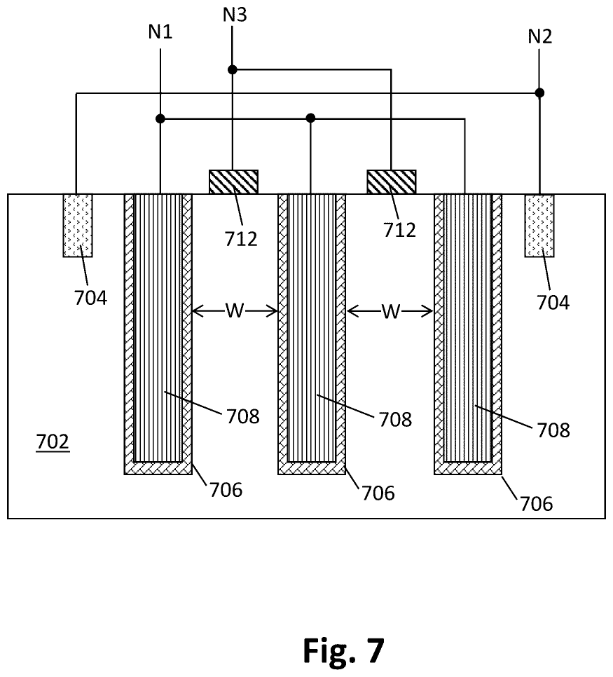

FIG. 7 is a diagram illustrating a cross section of another embodiment of an integrated bootstrap circuit. Description of FIG. 7 can reference components shown in FIG. 1 and FIG. 6. In the embodiment shown in FIG. 7, one or more trench MOS barrier Schottky diodes can implement boot diodes (e.g., DBOOT) and one or more trench MOS capacitors can implement boot capacitors (e.g., CBOOT). A cross section view of a portion of IC 116, that includes DBOOT and CBOOT, is shown in FIG. 7. In the example shown in FIG. 7, an N-well 702 that can be a part of IC 116 is shown. N-well 702 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 702 can be formed by implantation of dopant atoms such as Phosphorus or Arsenic. In some embodiments, N-well 702 can also be an N-epitaxial layer. N-well 702 can isolate bootstrap circuit components such as CBOOT and DBOOT from the rest of IC 116.

The bootstrap capacitor CBOOT shown in FIG. 1 can be implemented by one or more trench capacitors. The one or more trench capacitors can be formed in vacant areas or openings of N-well 702. A dielectric 706, an electrode 708 and the N-well 702 can implement a trench capacitor. In the embodiment shown in FIG. 7, three trench capacitors are shown but any arbitrary number of trench capacitors can be formed providing there is sufficient space in N-well 702. In one or more embodiments, N-well 702 can function as one of the conductive plates of the trench capacitors. Dielectric 706 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 708 can be formed by, for example, highly conductive materials such as doped polysilicon or metal (e.g., aluminum, copper, etc.). In one embodiment, dielectric 706 can have a thickness that is dependent on the voltage Vdd. By way of example, the thickness of dielectric 706 increase as Vdd increases such that capacitor CBOOT can be thick enough to block voltages greater than Vdd. Referring to FIG. 1, node N1 can be in contact with electrode 708. In comparison to embodiments that uses planar capacitors, trench capacitors can reduce the amount of surface areas being occupied by capacitor components on the surface of IC 116, and the three-dimensional (3D) nature of trench capacitors can provide more capacitance per unit area on the surface of IC 116.

In the embodiment shown in FIG. 7, diode DBOOT can be implemented by one or more trench metal oxide semiconductor (MOS) barrier Schottky (TMBS) diodes. To create the TMBS diodes, trench capacitors formed by dielectric 706 and electrode 708 are spaced apart by an equal distance W, where distance W can be predefined based on one or more specific criterions. One or more metal contacts 712 can be formed on N-well 702 and above the space between the trench capacitors. In one embodiment, the distance W can be predefined by selecting a value that causes the trench capacitors separated by the spacing W to create a Depletion MOS field-effect transistor (depletion MOSFET) under the P+ diffusion regions 710 to increase diode breakdown voltage while reducing surface area being occupied by DBOOT on N-well 702. The P+ diffusion regions 710 and the depletion MOSFET formed under metal contacts 712 and N-well 702 can form the TMBS diodes.

Metal contacts 712 can be Schottky contacts, which can be metal-semiconductor contacts that create Schottky barriers with an N-type semiconductor such as N-well 702. In one or more embodiments, metal contacts 712 can be Titanium, Cobalt or Platinum contacts. In an aspect, when a metal is in contact with an N-type semiconductor and the work function (e.g., the minimum energy required to extract one electron) of the metal is greater than the work function of the N-type semiconductor, then a Schottky barrier is formed. Hence, the material forming metal contacts 712 has a work function greater than the work function of the materials forming N-well 702. Metal contacts 712 can function as the anode of diode DBOOT and N-well 702 can function as the cathode of diode DBOOT. Referring to FIG. 1, node N3 can be in contact with metal contacts 712 such that the anode of diode DBOOT can be connected to Vdd.

One or more N+ diffusion regions 704 can be formed in N-well 702. The N+ diffusion regions 704 can be created by N-type diffusion in vacant areas of N-well 702. The N+ diffusion regions 704 can be formed by dopant materials such as Nitrogen, Phosphorus or Arsenic. N+ diffusion regions 704 can be used as contacts with other components. Referring to FIG. 1, node N2 can be in contact with N+ diffusion regions 704 to connect the cathode of diode DBOOT (e.g., N-well 702) to capacitor CBOOT.

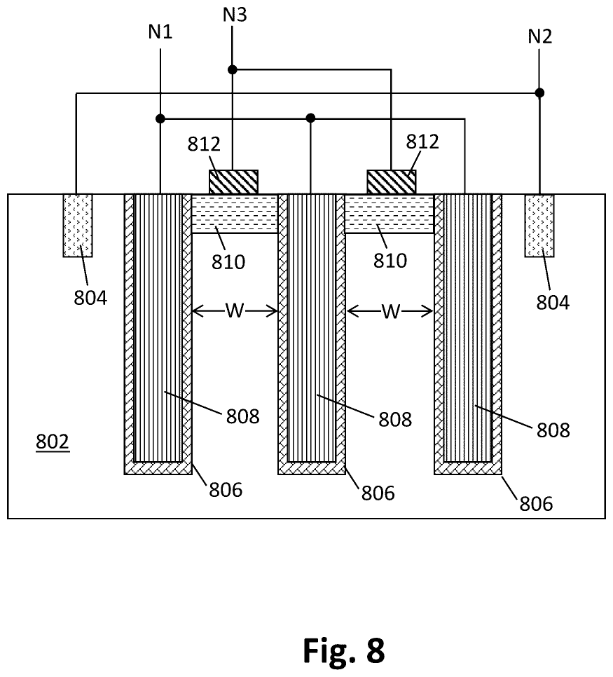

FIG. 8 is a diagram illustrating a cross section of another embodiment of an integrated bootstrap circuit. Description of FIG. 8 can reference components shown in FIG. 1 and FIG. 7. In the embodiment shown in FIG. 8, one or more trench MOS barrier PN diodes can implement boot diodes (e.g., DBOOT) and one or more trench MOS capacitors can implement boot capacitors (e.g., CBOOT). A cross section view of a portion of IC 116, that includes DBOOT and CBOOT, is shown in FIG. 8. In the example shown in FIG. 8, an N-well 802 that can be a part of IC 116 is shown. N-well 802 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 802 can be formed by implantation of dopant atoms such as Phosphorus or Arsenic. In some embodiments, N-well 802 can also be an N-epitaxial layer. N-well 802 can isolate bootstrap circuit components such as CBOOT and DBOOT from the rest of IC 116.

The bootstrap capacitor CBOOT shown in FIG. 1 can be implemented by one or more trench capacitors. The one or more trench capacitors can be formed in vacant areas or openings of N-well 802. A dielectric 806, an electrode 808 and the N-well 802 can implement a trench capacitor. In the embodiment shown in FIG. 8, three trench capacitors are shown but any arbitrary number of trench capacitors can be formed providing there is sufficient space in N-well 802. Dielectric 806 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 808 can be formed by, for example, highly conductive materials such as doped polysilicon or metal (e.g., aluminum, copper, etc.). In one embodiment, dielectric 806 can have a thickness that is dependent on the voltage Vdd. By way of example, the thickness of dielectric 806 increase as Vdd increases such that capacitor CBOOT can be thick enough to block voltages greater than Vdd. Referring to FIG. 1, node N1 can be in contact with electrode 808. In comparison to embodiments that uses planar capacitors, trench capacitors can reduce the amount of surface areas being occupied by capacitor components on the surface of IC 116, and the three-dimensional (3D) nature of trench capacitors can provide more capacitance per unit area on the surface of IC 116.

In the embodiment shown in FIG. 8, diode DBOOT can be implemented by one or more trench metal oxide semiconductor (MOS) barrier PN (TMBPN) diodes. To create the TMBPN diodes, trench capacitors formed by dielectric 806 and electrode 808 are spaced apart by an equal distance W, where distance W can be predefined based on one or more specific criterions. One or more P+ diffusion regions 810 can be created by P-type diffusion in vacant areas of N-well 802 within the space defined by spacing W. The P+ diffusion regions 810 can be formed by dopant materials such as Aluminum, Boron or Gallium. By forming P+ diffusion regions 810 in N-well 802, PN junctions can be formed between P+ diffusion regions 810 and N-well 802. One or more Ohmic contacts 812 can be formed on top of the P+ diffusion regions 810 to connect the TMBPN diodes to node N3. In one embodiment, the distance W can be predefined by selecting a value that causes the trench capacitors separated by the spacing W can create a Depletion MOS field-effect transistor (depletion MOSFET) under the P+ diffusion regions 810 to increase diode breakdown voltage while reducing surface area being occupied by DBOOT on N-well 802. The P+ diffusion regions 810 and the depletion MOSFET formed under metal contacts 812 and N-well 802 can form the TMBPN diodes. Referring to FIG. 1, node N3 can be in contact with contacts 812 such that the anode of diode DBOOT can be connected to Vdd.

One or more N+ diffusion regions 804 can be formed in N-well 802. The N+ diffusion regions 804 can be created by N-type diffusion in vacant areas of N-well 802. The N+ diffusion regions 804 can be formed by dopant materials such as Nitrogen, Phosphorus or Arsenic. N+ diffusion regions 804 can be used as contacts with other components. Referring to FIG. 1, node N2 can be in contact with N+ diffusion regions 804 to connect the cathode of diode DBOOT (e.g., N-well 802) to capacitor CBOOT.

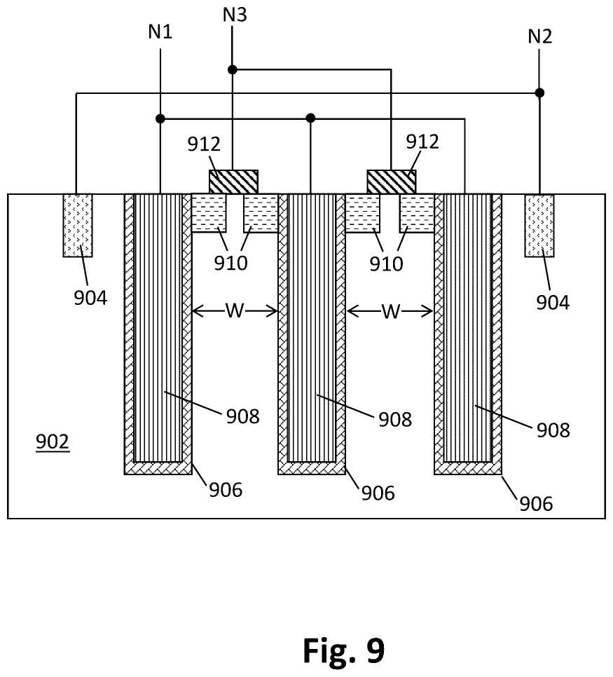

FIG. 9 is a diagram illustrating a cross section of another embodiment of an integrated bootstrap circuit. Description of FIG. 9 can reference components shown in FIG. 1 and FIG. 8. In the embodiment shown in FIG. 9, one or more trench MOS Junction barrier Schottky diodes can implement boot diodes (e.g., DBOOT) and one or more trench MOS capacitors can implement a boot capacitors (e.g., CBOOT). A cross section view of a portion of IC 116, that includes DBOOT and CBOOT, is shown in FIG. 9. In the example shown in FIG. 9, an N-well 902 that can be a part of IC 116 is shown. N-well 902 can be formed by techniques such as diffusion or ion implantation in open substrate surface areas (e.g., openings or trenches) in a P-type substrate (e.g., substrate made of P-type silicon) that can be a substrate of IC 116. In one or more embodiments, N-well 902 can be formed by implantation of dopant atoms such as Phosphorus or Arsenic. In some embodiments, N-well 902 can also be an N-epitaxial layer. N-well 902 can isolate bootstrap circuit components such as CBOOT and DBOOT from the rest of IC 116.

The bootstrap capacitor CBOOT shown in FIG. 1 can be implemented by one or more trench capacitors. The one or more trench capacitors can be formed in vacant areas or openings of N-well 902. A dielectric 906, an electrode 908 and the N-well 902 can implement a trench capacitor. In the embodiment shown in FIG. 9, three trench capacitors are shown but any arbitrary number of trench capacitors can be formed providing there is sufficient space in N-well 902. In one or more embodiments, N-well 902 can function as one of the conductive plates of the trench capacitors. Dielectric 906 can be formed by, for example, Silicon Dioxide (SiO2), Silicon Nitride (Si3N4), or various high-k dielectrics such as Hafnium Dioxide (HfO2), Aluminum Oxide (Al2O3). Note that high-k dielectrics can increase capacitance per unit area, allowing for higher capacitance value in smaller device sizes. Electrode 908 can be formed by, for example, highly conductive materials such as doped polysilicon or metal (e.g., aluminum, copper, etc.). In one embodiment, dielectric 906 can have a thickness that is dependent on the voltage Vdd. By way of example, the thickness of dielectric 906 increase as Vdd increases such that capacitor CBOOT can be thick enough to block voltages greater than Vdd. Referring to FIG. 1, node N1 can be in contact with electrode 908. In comparison to embodiments that uses planar capacitors, trench capacitors can reduce the amount of surface areas being occupied by capacitor components on the surface of IC 116, and the three-dimensional (3D) nature of trench capacitors can provide more capacitance per unit area on the surface of IC 116.

In the embodiment shown in FIG. 9, diode DBOOT can be implemented by one or more trench metal oxide semiconductor (MOS) barrier junction barrier Schottky (TMBJBS) diodes. One or more P+ diffusion regions 910 can be created by P-type diffusion inside N-well 902 within the space defined by spacing W, where distance W can be predefined based on one or more specific criterions. The P+ diffusion regions 910 can be formed by dopant materials such as Aluminum, Boron or Gallium. By forming P+ diffusion regions 910 in N-well 902, PN junctions can be formed between P+ diffusion regions 910 and N-well 902. After forming the P-type diffusion regions 910, one or more metal contacts 912 can be formed straddling on N-well 902 and on the P-type diffusion regions 910. Metal contacts 912 can be Ohmic on top of P-type diffusion region 910 and form a PN junction diode and Schottky diode on top of N-well 902. One or more metal contacts 912 can be formed on top of the P+ diffusion regions 910. The P+ diffusion regions 910 can be positioned such that metal contacts 912 can contact N-well 902. In one embodiment, the distance W can be predefined by selecting a value that causes the trench capacitors separated by the spacing W can create a Depletion MOS field-effect transistor (depletion MOSFET) under the P+ diffusion regions 910 to increase diode breakdown voltage while reducing surface area being occupied by DBOOT on N-well 902. The P+ diffusion regions 910 and the depletion MOSFET formed under metal contacts 912 and N-well 802 can form the TMJBS diodes. By forming P+ diffusion regions 910 in N-well 402, PN junctions can surround Schottky diodes formed by metal contacts 912 and N-well 902. The spacing between the P+ diffusion regions 910 can be defined for optimized blocking and conduction.

Metal contacts 912 can be Schottky contacts, which can be metal-semiconductor contacts that create Schottky barriers with an N-type semiconductor such as N-well 902. In one or more embodiments, metal contacts 912 can be Titanium, Cobalt or Platinum contacts. In an aspect, when a metal is in contact with an N-type semiconductor and the work function (e.g., the minimum energy required to extract one electron) of the metal is greater than the work function of the N-type semiconductor, then a Schottky barrier is formed. Hence, the material forming metal contacts 912 has a work function greater than the work function of the materials forming N-well 902. Metal contacts 912 can function as the anode of diode DBOOT and N-well 902 can function as the cathode of diode DBOOT. Referring to FIG. 1, node N3 can be in contact with metal contacts 912 such that the anode of diode DBOOT can be connected to Vdd.

One or more N+ diffusion regions 904 can be formed in N-well 902. The N+ diffusion regions 904 can be created by N-type diffusion in vacant areas of N-well 902. The N+ diffusion regions 904 can be formed by dopant materials such as Nitrogen, Phosphorus or Arsenic. N+ diffusion regions 904 can be used as contacts with other components. Referring to FIG. 1, node N2 can be in contact with N+ diffusion regions 904 to connect the cathode of diode DBOOT (e.g., N-well 902) to capacitor CBOOT.

In one embodiment, an IC package 1000 including IC 116 can be a monolithic IC including a voltage regulator and bootstrap circuit that includes bootstrap capacitor CBOOT and bootstrap diode DBOOT as shown in FIG. 1 to FIG. 9. By including bootstrap capacitor CBOOT and bootstrap diode DBOOT in IC 116, there is no need to use pins to connect discrete capacitors and diodes to voltage regulator IC in the IC package.

Among the different embodiments shown herein, embodiments that utilize planar capacitors can be relatively easy to manufacture since production techniques of planar capacitors are commonly in place. Also, manufacturing planar capacitors can utilize gate level oxides which does not result in additional process complexity thus providing relatively high quality capacitors. In some examples, if IC 116 does not have sufficient surface area, then the number and size of planar capacitors can be limited and thus result in limited capacitance. Embodiments that utilize trench capacitors can provide higher capacitance per unit area when compared to planar capacitors. Manufacturing of trench capacitors may be relatively more complex when compared to planar capacitors, and can also have higher wafer cost. Therefore, the different embodiments presented herein provide flexibility in integrating bootstrap circuit components with voltage regulators in a single IC package. Integration of bootstrap circuit components with voltage regulators in a single IC package can preserve board area on the PCB and can allow higher capacitance for the bootstrap circuit while using the same board area as conventional systems that utilized discrete bootstrap circuit components.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present invention have been presented for purposes of illustration and description but are not intended to be exhaustive or limited to the invention in the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. An integrated circuit comprising:
a power stage;
a driver configured to drive the power stage;
a bootstrap circuit configured to drive a high-side switch in the power stage in a start-up process, the bootstrap circuit comprising a capacitor and a diode, wherein:
the power stage, the driver and the bootstrap circuit are integrated on the same silicon;
the capacitor is implemented by at least one of a planar capacitor and a trench capacitor; and
the diode is implemented by at least one of a planar diode and a trench diode.

2. The integrated circuit of claim 1, wherein:
the capacitor is implemented by at least one planar capacitor; and
the diode is implemented by at least one planar diode that comprises PN junction diode.

3. The integrated circuit of claim 1, wherein:
the capacitor is implemented by at least one planar capacitor; and
the diode is implemented by at least one planar diode that comprises a Schottky diode.

4. The integrated circuit of claim 1, wherein:
the capacitor is implemented by at least one planar capacitor; and
the diode is implemented by at least one planar diode that comprises a junction barrier Schottky diode.

5. The integrated circuit of claim 1, wherein:
the capacitor is implemented by at least one trench capacitor; and
the diode is implemented by at least one planar diode that comprises a PN junction diode.

6. The integrated circuit of claim 1, wherein:
the capacitor is implemented by at least one trench capacitor; and
the diode is implemented by at least one trench diode that comprises a trench Schottky diode.

7. The integrated circuit of claim 1, wherein:
the capacitor is implemented by at least one trench capacitor; and
the diode is implemented by at least one trench metal-oxide semiconductor barrier Schottky diode.

8. The integrated circuit of claim 1, wherein:
the capacitor is implemented by at least one trench capacitor; and
the diode is implemented by at least one trench metal-oxide semiconductor barrier PN junction diode.

9. The integrated circuit of claim 1, wherein:
the capacitor is implemented by at least one trench capacitor; and
the diode is implemented by at least one trench metal-oxide semiconductor junction barrier Schottky diode.

10. A voltage regulator comprising:
an integrated circuit;
a controller configured to control the integrated circuit;
the integrated circuit comprising:
a power stage;
a driver configured to drive the power stage;
a bootstrap circuit configured to drive a high-side switch in the power stage in a start-up process, the bootstrap circuit comprising a capacitor and a diode, wherein:
the power stage, the driver and the bootstrap circuit are integrated on the same silicon;
the capacitor is implemented by at least one of a planar capacitor and a trench capacitor; and
the diode is implemented by at least one of a planar diode and a trench diode.

11. The voltage regulator of claim 10, wherein:
the capacitor is implemented by at least one planar capacitor; and
the diode is implemented by at least one planar diode that comprises PN junction diode.

12. The voltage regulator of claim 10, wherein:
the capacitor is implemented by at least one planar capacitor; and
the diode is implemented by at least one planar diode that comprises a Schottky diode.

13. The voltage regulator of claim 10, wherein:
the capacitor is implemented by at least one planar capacitor; and
the diode is implemented by at least one planar diode that comprises a junction barrier Schottky diode.

14. The voltage regulator of claim 10, wherein:
the capacitor is implemented by at least one trench capacitor; and
the diode is implemented by at least one planar diode that comprises a PN junction diode.

15. The voltage regulator of claim 10, wherein:
the capacitor is implemented by at least one trench capacitor; and
the diode is implemented by at least one trench diode that comprises a trench Schottky diode.

16. The voltage regulator of claim 10, wherein:
the capacitor is implemented by at least one trench capacitor; and
the diode is implemented by at least one trench metal-oxide semiconductor barrier Schottky diode.

17. The voltage regulator of claim 10, wherein:
the capacitor is implemented by at least one trench capacitor; and
the diode is implemented by at least one trench metal-oxide semiconductor barrier PN junction diode.

18. The voltage regulator of claim 10, wherein:
the capacitor is implemented by at least one trench capacitor; and
the diode is implemented by at least one trench metal-oxide semiconductor junction barrier Schottky diode.

19. An integrated circuit comprising:
a power stage;
a driver configured to drive the power stage;
a bootstrap circuit configured to drive a high-side switch in the power stage in a start-up process, the bootstrap circuit comprising a capacitor and a diode, wherein:
the power stage, the driver and the bootstrap circuit are integrated on the same silicon; and
the capacitor is implemented by at least one trench capacitor.

20. The integrated circuit of claim 19, wherein the diode is implemented by at least one of a planar diode and a trench diode.
